(19) United States
(12) Patent Application Publication
(10) Pub. No.: US 2017/0066890 A1
(43) Pub. Date: Mar. 9, 2017

(54) MULTI-LAYER STRUCTURE HAVING GOOD UV PROTECTION AND SCRATCH PROTECTION

(71) Applicant: COVESTRO DEUTSCHLAND AG, Leverkusen (DE)

(72) Inventors: Rafae OSER, Krefeld (DE); Tim KUHLMANN, Leichlingen (DE); Stefan MERLI, Jettingen (DE); Andreas SCHULZ, Leonberg (DE); Matthias WALKER, Gerlingen (DE)

(21) Appl. No.: 15/123,017

(22) PCT Filed: Feb. 27, 2015
(86) PCT No.: PCT/EP2015/054151

§ 371 Date: Sep. 1, 2016

(30) Foreign Application Priority Data
Mar. 4, 2014 (EP) 14157652.0

(51) Int. Cl. C08J 7/06; C23C 14/22; C23C 16/50

(52) U.S. Cl. CPC C08J 7/06; C23C 16/50; C23C 14/22; C08J 2300/22

(57) ABSTRACT

The invention relates to a multi-layer structure containing a thermoplastic substrate, a barrier layer, a UV protection layer, and a cover layer: 1. a thermoplastic substrate material, 2. a barrier coat containing silicon-based precursors, 3. a UV protection layer based on a metal oxide (Me_{y}Oₓ) having a composition of Me_{y}/Oₓ>1, preferably >1.2, wherein the metal oxide is selected from the group diethyl zinc, zinc acetate, triisopropyl titanate, tetraisopropyl titanate, cerium-β-diketonate, and cerammonium nitrate, 4. a covering layer, wherein the covering layer is formed of a silicon-based precursor having an element gradient in the oxygen concentration and/or carbon or hydrocarbon concentration, wherein the oxygen content of the cover layer close to the UV light-absorbing layer is less than on the opposite side of the cover layer and the carbon content close to the UV light-absorbing layer greater than on the opposite side of the cover layer, which is characterised by an excellent abrasion protection and a long-term resistance to ageing.

The present invention relates to a multilayer structure containing a thermoplastic substrate, a barrier layer, a UV protection layer and a covering layer, which multilayer structure displays excellent abrasion protection and also long-term aging resistance.

The use of thermoplastics in exterior applications is frequently made possible only by an additionally applied protective layer on the thermoplastic support material. This protective layer has the task of protecting the thermoplastic support material against mechanical and chemical environmental influences and also against radiation-related damage. The application of coating materials, for example a combination of bonding layers which protect against UV radiation with scratch resistant coatings based on sol-gel chemistry, is widespread and employed in many exterior applications. These have not only economic hurdles but also technical limitations. The application is in the case of high-quality optical components carried out by the flooding process, which results in formation of a layer thickness gradient on the thermoplastic support, which is the cause of formation of nonuniform layer properties. Thus, the layer hardness, as a measure of the scratch resistance or abrasion resistance and also the aging resistance of the surface-coated component on exposure to damaging UV radiation, depends not only on the composition but also on the layer thicknesses of the individual layers. The performance and quality of the surface-modified thermoplastics obtained in this way is limited, inter alia, because of the reproducibility of the desired properties.

To overcome the abovementioned deficiencies, protective layers which are deposited by physical or chemical vapor deposition on the thermoplastic support material have been proposed as alternatives to the application of flowable coating compositions. Disadvantages of physical vapor deposition are the high energy input and the associated high heat input acting on the support material to be modified. Thermoplastic support materials, for example polymethyl methacrylate (PMMA) or polycarbonate (PC), can deform if the input is too high, as a result of which the quality of the component to be protected is reduced. The use of chemical vapor deposition for forming protective layers on thermoplastic support materials is widespread and there is thus no lack of various approaches to providing protective layers for thermoplastic support materials and methods for depositing the respective protective layers in the literature.

To deposit covering layers by means of chemical vapor deposition, use is frequently made of silicon-based precursors, for example silanes, disilanes, tetramethyldisiloxane (TMDSO), hexamethyldisiloxane (HMDSO), tetraethyl orthosilicate (TEOS), hexamethyldisilanes, octamethylcyclotetrasiloxane (D4) or tetramethylcyclotetrasiloxanes. A selection is mentioned in the documents DE2650048, EP0252870 and U.S. Pat. No. 5,298,587. These precursors then deposit, after oxidation by means of oxygen, as a silicon dioxide layer having a partially regulatable organic content on the surface of the thermoplastic support.

The different coefficients of thermal expansion of thermoplastic support material and the layer to be applied is overcome by formation of a gradient layer as described by way of example in the documents DE3413019, U.S. Pat. No. 4,927,704, U.S. Pat. No. 5,051,308, EP0267679 and WO 97/13802. Here, it should be mentioned that the gradient layer directly adjoins the thermoplastic support material.

In the deposition of layers for protection against UV radiation by means of chemical vapor deposition, metal-organic compounds such as diethylzinc (DEZ), zinc acetate, triisopropyl titanate, tetraisopropyl titanante (TTIP), cerium β-diketonate and also cerium ammonium nitrate are frequently utilized. The resulting layers contain, for example, titanium, cerium, iron, zinc, vanadium, yttrium, indium, tin and zirconium, with these having, as deposited oxide, nitride or oxynitride, the property of absorbing short wavelength radiation in the wavelength range from 280 nm to 380 nm.

The use of various precursors and the properties of the resulting UV light-absorbing inorganic layers are described in more detail in extracts in the following documents.
Nizard et al.: “Deposition of titanium dioxide from TTIP by plasma enhanced and remote plasma enhanced chemical vapour deposition” (2008), Surface and Coating Technology 202, pages 4076-4085.
H. J. Frenck et al.: “Depopsition of TiO₂ thin films plasma-enhanced decomposition of tetraiso-propyltitanate” (1991), Thin Solid Films, 201, pages 327-335.
Barreca et al.: Nucleation and growth of nanophasic CeO₂ thin films by plasma enhanced CVD” (2003), Chemical Vapor Deposition 9, pages 199-206.
Kerstin Lau, “Plasmagestützte Aufdampfprozesse für die Herstellung haftfester optischer Beschichtungen auf Bisphenol-A Polycarbonat” (2006), thesis.

EP 887437 A describes a process for depositing an adhering coating to the surface of a substrate by plasma deposition, which comprises formation of an oxygen-containing plasma by means of a DC electric arc plasma generator, injection of a reactant gas into the plasma outside the plasma generator, direction of the plasma into a vacuum chamber by means of a divergent nozzle injector which extends from the plasma generator in the vacuum chamber to the substrate which is arranged in the vacuum chamber, as a result of which reactive species formed from the oxygen and the reactant gas contact the surface of the substrate for a time sufficient to form the adhering coating. A disadvantage of the use of the DC electric arc plasma generator is the high energy input into the substrate to be coated, as a result of which deformations can occur. The resulting protective layer can consist essentially of silicon oxide or of zinc oxide or titanium oxide. A combination of the two layers is not described. Zinc oxide as sole protective layer is not stable to hydrolysis and is not usable in the long term in the form described. No details are given about the precise composition of the ZnO layer.

DE10012516 is concerned with a component having a transparent, scratch-resistant protective layer which is impermeable to UV radiation, where the protective layer is a gradient layer consisting of silicon, hydrocarbon radicals and a metal selected from a group whose oxides absorb UV radiation, with the silicon and oxygen content increasing in an outward direction and the metal content in the layer having a maximum and decreasing in an outward direction and to the component side. The metal here is selected from the group consisting of titanium, cerium, iron, zinc, vanadium, yttrium, indium, tin and zirconium. In this process, the metal oxide formed is embedded in the scratch resistant layer which forms. Disadvantages are the complicated process with simultaneous deposition of a plurality of layer constituents and also the lack of reproducibility of the layer quality. Since the metal oxide is randomly distributed in the matrix, the hydrolysis stability of the metal oxide can also not be ensured in such a structure. No details are given about a precise composition of the metal oxide layer.

DE10153760 relates to a process for producing UV-absorbing transparent abrasion protection layers by vacuum coating, in which at least one inorganic compound which forms layers having a high abrasion resistance and an inorganic compound which forms layers having high UV absorption are deposited on a substrate either simultaneously or directly after one another in time, in each case by reactive or partially reactive plasma-enhanced high-rate vapor deposition. The deposition of zinc oxide as UV-absorbing layer embedded in silicon dioxide as abrasion protection layer is described as preferred embodiment. In this way, the zinc oxide is protected against external influences. No details are given about a precise composition of the zinc oxide layer. A disadvantage is the chosen deposition process of electron beam high-grade vapor deposition of, for example, zinc oxide since this process can be implemented only with a high outlay in the process of chemical vapor deposition of further layers. Furthermore, high process temperatures are used in order to attain economical speeds, and these can lead to deformation of the thermoplastic support material.

U.S. Pat. No. 5,156,882 A describes a method of forming a transparent, abrasion-resistant and UV light-absorbing component containing an intermediate layer of a resin-like bonding agent composition, a layer based on a UV-absorbing composition selected from the group consisting of zinc oxide, titanium dioxide, cerium dioxide and vanadium pentoxide on the abovementioned intermediate layer and also a final, abrasion-resistant layer on the previous layer, characterized in that all layers have been deposited by plasma-enhanced chemical vapor deposition (PE-CVD). No details of a precise composition of the metal oxide layer and of the covering layer are given. Nothing is said about the aging resistance of the layer sequence. Furthermore, the deposition rates achieved in the process employed cannot be scaled up economically because of the use of a high-frequency plasma.

DE19901834 describes a process in 6 steps for depositing a 4-layer system on polymers, in which a soft, low-oxygen covering layer composed of HMDSO is formed without utilization of oxygen. Furthermore, an organic UV absorber is used in the deposition of a UV protection layer. This document, too, gives no indication of the stoichiometric compositions of the individual layers. The use of organic UV absorbers in the process of chemical vapor deposition leads, according to present-day knowledge, to layer systems which are not aging resistant and have a limited layer quality. This is described further by the documents PCT/EP2013/067210 (unpublished), DE19924108, DE19522865, FR2874606 and WO 1999/055471.

WO 2012/143150 A1 describes the use of aluminum oxide as barrier layer in the structure.

DE10 2010 006134 A1 describes the use of SiO₂ rather than the SiOxCyHz of the present application and also the use of organic UV absorbers for the deposition of absorbing layers.

WO 2006/002768 A1 describes dark-colored, nontransparent structures which are not based on the concept of the present invention.

WO 2003/038141 A2 describes a layer composite which is produced by high-rate vapor deposition and is composed of SiOx/ZnOx/SiOx on a substrate; no gradient in the outer layer is described.

The following documents are specifically concerned with UV protection layers based on zinc oxide for protecting polycarbonate as thermoplastic support. A precise recommendation as to how the stoichiometric ratio in the zinc oxide in the UV protection layer is to be chosen in order to obtain long-term aging protection for the thermoplastic structure is not mentioned. Furthermore, there is no information on incorporation of the UV protection layer into functional layers for eliminating the hydrolysis sensitivity of the starting material. The embodiment of a potential covering layer is likewise not discussed.
Anma, H.: “Preparation of zinc oxide thin films deposited by plasma chemical vapor deposition for application to ultraviolet-cut coating” (2001), Japanese Journal of Applied Physics, Part 1: Regular Papers, Short Notes & Review Papers, volume 40, issue 10, pages 6099-6103.
Moustaghfir, A. et al.: “Sputtered zinc oxide coatings: structural study and application to the photoprotection of the polycarbonate” (2004), Surface and Coatings Technology, volume 180-181, pages 642-645, ISSN: 0257-8972.
Moustaghfir, A. et al.: “Photostabilization of polycarbonate by ZnO coatings” (2005), Journal of Applied Polymer Science, volume 95, issue 2, pages 380-385, ISSN: 0021-8995.
Merli, S. et al.: “Hochrateabscheidung mit einem Mikrowellenplasma Mit Duo-Plasmaline abgeschiedenes Siliziumoxid verleiht Polycarbonat die Kratzfestigkeit von Glas” (2013), Vakuum in Forschung und Praxis, volume 25, issue 2, pages 33-40, ISSN: 0947-076X.
Merli, S. et al.: “PECVD of Zinc Oxide as UV Protection Coating” (2012), Annual Report 2012 of the Institute for Plasma Research of the University of Stuttgart, page 46.
Merli, S. et al.: “Transparent UV- and scratch protective coatings on polycarbonate” (2013), Annual Report 2013 of the Institute for Plasma Research of the University of Stuttgart, page 14.

There is accordingly no adequate teaching on the design of a layer system for thermoplastic support materials, which ensures not only excellent abrasion protection but also long-term aging resistance, to be found in the prior art. Furthermore, there is a lack of a precise description of a method of achieving these properties taking into account economic aspects.

It is an object of the present invention to provide layer systems for thermoplastic support materials, which layer systems display excellent abrasion protection and also long-term aging resistance and in terms of quality and layer stability are not known in the prior art. A further constituent is provision of an economic process for producing such layer systems on thermoplastic substrates on the basis of a high-rate process and also the provision of shaped bodies which have been produced by the high-rate process.

It has surprisingly been found that the object of the present invention is achieved by a multilayer structure containing, in the following order,

1. a thermoplastic support material,
2. a barrier layer,
3. a UV protection layer based on a metal oxide (Me_{y}Oₓ) having a composition of Me_{y}/Oₓ>1, preferably >1.2,
4. a covering layer having an element gradient in the oxygen concentration and/or carbon or hydrocarbon concentration.

The layers are deposited on the thermoplastic support by plasma-enhanced chemical vapor deposition.

### Thermoplastic Support Material

The thermoplastic support material to be coated can be a thermoplastically processible material.

Thermoplastically processible materials in the context of the invention are preferably polycarbonate, copolycarbonate, polyester carbonate, polystyrene, styrene copolymers, aromatic polyesters such as polyethylene terephthalate (PET), PET-cyclohexanedimethanol copolymer (PETG), polyethylene naphthalate (PEN), polybutylene terephthalate (PBT), aliphatic polyolefins such as polypropylene or polyethylene, cyclic polyolefin, polyacrylates or copolyacrylates and polymethacrylate or copolymethacrylate, e.g. polymethyl methacrylates or copolymethyl methacrylates (e.g. PMMA), and also copolymers with styrene, e.g. transparent polystyrene-acrylonitrile (PSAN), thermoplastic polyurethanes, polymers based on cyclic olefins (e.g. TOPAS®, a commercial product form Ticona), polycarbonate blends with olefinic copolymers or graft polymers, for example styrene-acrylonitrile copolymers. Here, the abovementioned polymers can be used either alone or in mixtures.

Preference is given to polycarbonate, copolycarbonate, polyester carbonate, aliphatic polyolefins such as polypropylene or polyethylene, cyclic polyolefin, PET or PETG and also polyacrylates or copolyacrylates and polymethacrylate or copolymethacrylate, e.g. polymethyl methacrylates or copolymethyl methacrylates, and also mixtures of the abovementioned polymers.

Particular preference is given to polycarbonate, copolycarbonate, polyester carbonate, PET or PETG and also polyacrylates or copolyacrylates and polymethacrylate or copolymethacrylate, e.g. polymethyl methacrylates or copolymethyl methacrylates, and also mixtures of the abovementioned polymers.

Very particular preference is given to using a polycarbonate and/or a copolycarbonate as thermoplastic support material (also referred to as polymer substrate). Furthermore, a blend system containing at least one polycarbonate or copolycarbonate is also preferred.

According to the invention, the polymer substrates to which the subsequent layers are applied can be made up of one or more layers and have been precoated with any other layers.

### Polycarbonates

For the purposes of the invention, polycarbonates encompass homopolycarbonates, copolycarbonates and also polyester carbonates as are described in EP 1 657 281 A.

Aromatic polycarbonates are prepared, for example, by reacting diphenols with carbonic acid halides, preferably phosgene, and/or with aromatic dicarboxylic acid dihalides, preferably benzenedicarboxylic acid dihalides, by the phase interface process, optionally using chain terminating agents, for example monophenols, and optionally using trifunctional branching agents or branching agents having a functionality of more than three, for example triphenols or tetraphenols. A preparation via a melt polymerization process by reacting diphenols with, for example diphenyl carbonate is likewise possible.

Diphenols for preparing the aromatic polycarbonates and/or aromatic polyester carbonates are preferably those of the formula (I)

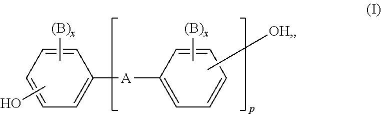

where
A is a single bond, C1-C5-alkylene, C2-C5-alkylidene, C5-C6-cycloalkylidene, —O—, —SO—, —CO—, —S—, —SO₂—, C6-C12-arylene onto which further aromatic, optionally heteroatom-containing rings can be condensed,

or a radical of the formula (II) or (Ill)

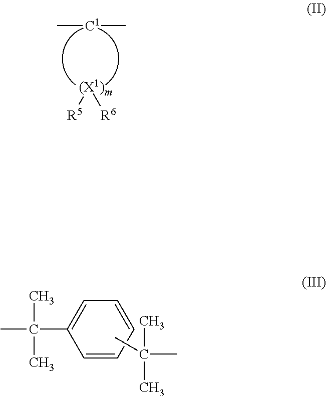

B is in each case C1-C12-alkyl, preferably methyl, halogen, preferably chlorine and/or bromine,
x is in each case independently 0, 1 or 2,
p is 1 or 0, and
R5 and R6 can be selected individually for each X1 and are, independently of one another, hydrogen or C1-C6-alkyl, preferably hydrogen, methyl or ethyl,
X1 is carbon and
m is an integer from 4 to 7, preferably 4 or 5, with the proviso that R5 and R6 are both alkyl on at least one atom X1.

Diphenols suitable for preparing the polycarbonates are, for example, hydroquinone, resorcinol, dihydroxybiphenyls, bis(hydroxyphenyl)alkanes, bis(hydroxyphenyl)cycloalkanes, bis(hydroxyphenyl) sulfides, bis(hydroxyphenyl) ethers, bis(hydroxyphenyl) ketones, bis(hydroxyphenyl) sulfones, bis(hydroxyphenyl) sulfoxides, alpha,alpha′-bis(hydroxyphenyl)diisopropylbenzenes, phthalimidines derived from isatin or phenolphthalein derivates and also ring-alkylated and ring-halogenated compounds thereof.

Preferred diphenols are 4,4′-dihydroxybiphenyl, 2,2-bis(4-hydroxyphenyl)propane, 2,4-bis(4-hydroxyphenyl)-2-methylbutane, 1,1-bis(4-hydroxyphenyl)-p-diisopropylbenzene, 2,2-bis(3-methyl-4-hydroxyphenyl)propane, 2,2-bis(3-chloro-4-hydroxyphenyl)propane, bis(3,5-dimethyl-4-hydroxy-phenyl)methane, 2,2-bis(3,5-dimethyl-4-hydroxyphenyl)propane, bis(3,5-dimethyl-4-hydroxyphenyl) sulfone, 2,4-bis(3,5-dimethyl-4-hydroxyphenyl)-2-methylbutane, 1,1-bis(3,5-dimethyl-4-hydroxy-phenyl)-p-diisopropylbenzene, 2,2-bis(3,5-dichloro-4-hydroxyphenyl)propane, 2,2-bis(3,5-dibromo-4-hydroxyphenyl)propane, 1,1-bis(4-hydroxyphenyl)-3,3,5-trimethylcyclohexane, and 2-hydrocarbyl-3,3-bis(4-hydroxyaryl)phthalimidines and also the reaction product of N-phenylisatin and phenol.

Particular preferred diphenols are 2,2-bis(4-hydroxyphenyl)propane, 2,2-bis(3,5-dimethyl-4-hydroxyphenyl)propane, 2,2-bis(3,5-dichloro-4-hydroxyphenyl)propane, 2,2-bis(3,5-dibromo-4-hydroxyphenyl)propane, 1,1-bis(4-hydroxyphenyl)cyclohexane and 1,1-bis(4-hydroxyphenyl)-3,3,5-trimethylcyclohexane. In the case of the homopolycarbonates, only one diphenol is used, while in the case of copolycarbonates, a plurality of diphenols are used. Suitable carbonic acid derivatives are, for example, phosgene or diphenyl carbonate.

Suitable chain termination agents which can be used in the preparation of the polycarbonates are both monophenols and monocarboxylic acids. Suitable monophenols are phenol itself, alkylphenols such as cresols, p-tert-butylphenol, cumylphenol, p-n-octylphenol, p-isooctylphenol, p-n-nonylphenol and p-isononylphenol, halophenols such as p-chlorophenol, 2,4-dichlorophenol, p-bromophenol and 2,4,6-tribromophenol, 2,4,6-triiodophenol, p-iodophenol, and also mixtures thereof. Preferred chain termination agents are phenol, cumylphenol and/or p-tert-butylphenol.

Particularly preferred polycarbonates in the context of the present invention are homopolycarbonates based on bisphenol A and copolycarbonates based on the monomers selected from at least one of the group consisting of bisphenol A, 1,1-bis(4-hydroxyphenyl)-3,3,5-trimethylcyclohexane, 2-hydrocarbyl-3,3-bis(4-hydroxyaryl)phthalimidines and the reaction products of N-phenylisatin and phenol. The polycarbonates can, in a known manner, be linear or branched. The proportion of comonomers based on bisphenol A is generally up to 60% by weight, preferably up to 50% by weight, particularly preferably from 3 to 30% by weight. Mixtures of homopolycarbonate and copolycarbonates can likewise be used.

Polycarbonates and copolycarbonates containing 2-hydrocarbyl-3,3-bis(4-hydroxyaryl)phthalimidines as monomers are known from, inter alia, EP 1 582 549 A1. Polycarbonates and copolycarbonates containing bisphenol monomers based on reaction products of N-phenylisatin and phenol are described, for example, in WO 2008/037364 A1.

Polycarbonate-polysiloxane block cocondensates are likewise suitable. The block cocondensates preferably contain blocks of dimethylsiloxane. The preparation of polysiloxane-polycarbonate block cocondensates is described, for example, in U.S. Pat. No. 3,189,662 A, U.S. Pat. No. 3,419,634 A and EP 0 122 535 A1. The block cocondensates preferably contain from 1% by weight to 50% by weight, preferably from 2% by weight to 20% by weight, of dimethylsiloxane.

The thermoplastic, aromatic polycarbonates have average molecular weights (weight average Mw, measured by GPC (gel permeation chromatography) using a polycarbonate standard) of from 10 000 g/mol to 80 000 g/mol, preferably from 14 000 g/mol to 32 000 g/mol, particularly preferably from 18 000 g/mol to 32 000 g/mol. In the case of injection-molded shaped polycarbonate parts, the preferred average molecular weight is from 20 000 g/mol to 29 000 g/mol. In the case of extruded shaped polycarbonate parts, the preferred average molecular weight is from 25 000 g/mol to 32 000 g/mol.

The thermoplastic polymers for the support layer can additionally contain fillers. In the context of the present invention, fillers have the task of reducing the coefficient of thermal expansion of the polycarbonate and of regulating, preferably reducing, the permeability of gases and water vapor. Suitable fillers are glass spheres, hollow glass spheres, glass flakes, carbon blacks, graphites, carbon nanotubes, quartzes, talc, mica, silicates, nitrides, wollastonite, and also pyrogenic or precipitated silicas, with the silicas having BET surface areas of at least 50 m²/g (in accordance with DIN 66131/2).

Preferred fibrous fillers are metallic fibers, carbon fibers, polymer fibers, glass fibers or milled glass fibers, with particular preference being given to glass fibers or milled glass fibers.

Preferred glass fibers also include those which are used in the embodiments of continuous fibers (rovings), long glass fibers and chopped glass fibers, which are produced from M, E, A, S, R or C glass, with E, A, or C glass being more preferred. The diameter of the fibers is preferably from 5 μm to 25 μm, more preferably from 6 μm to 20 μm, particularly preferably from 7 μm to 15 μm. Long glass fibers preferably have a length of from 5 μm to 50 mm, more preferably from 5 μm to 30 mm, even more preferably from 6 μm to 15 mm, and particularly preferably from 7 μm to 12 mm; they are described, for example, in WO 2006/040087 A1. The chopped glass fibers preferably comprise at least 70% by weight of glass fibers having a length of more than 60 μm. Further inorganic fillers are inorganic particles having a particle shape selected from the group consisting of spherical, cubic, tabular, disk-like and platelet-like geometries. Inorganic fillers having a spherical or platelet-like shape, preferably in finely divided and/or porous form having a large external and/or internal surface area, are particularly suitable. These are preferably thermally inert inorganic materials, in particular ones based on nitrides such as boron nitride, oxides or mixed oxides such as cerium oxide, aluminum oxide, carbides such as tungsten carbide, silicon carbide or boron carbide, powdered quartz such as quartz flour, amorphous SiO₂, milled sand, glass particles such as glass powder, in particular glass spheres, silicates or aluminosilicates, graphite, in particular high-purity synthetic graphite. Particular preference is given to quartz and talc, most preferably quartz (spherical particle shape). These fillers are characterized by an average diameter d50% of from 0.1 μm to 10 μm, preferably from 0.2 μm to 8.0 μm, more preferably from 0.5 m to 5 μm.

Silicates are characterized by an average diameter d50% of from 2 m to 10 μm, preferably from 2.5 μm to 8.0 μm, more preferably from 3 μm to 5 μm, and particularly preferably 3 μm, with an upper diameter d95% of from 6 μm to 34 μm, more preferably from 6.5 μm to 25.0 μm, even more preferably from 7 μm to 15 μm, and particularly preferably 10 μm, being preferred. The silicates preferably have a specific BET surface area, determined by nitrogen adsorption in accordance with ISO 9277, of from 0.4 m²/g to 8.0 m²/g, more preferably from 2 m²/g to 6 m²/g, and particularly preferably from 4.4 m²/g to 5.0 m²/g. More preferred silicates have a maximum of only 3% by weight of secondary constituents, with preference being given to the Al₂O₃ content being <2.0% by weight, the Fe₂O₃ content being <0.05% by weight, the (CaO+MgO) content being <0.1% by weight, the (Na₂O+K₂O) content being <0.1% by weight), in each case based on the total weight of the silicate.

Further silicates use wollastonite or talc in the form of finely milled grades having an average particle diameter d50 of <10 μm, preferably <5 μm, particularly preferably <2 μm, very particularly preferably <1.5 μm. The particle size distribution is determined by air classification. The silicates can have a coating composed of silicon-organic compounds, with preference being given to using epoxysilane, methylsiloxane, and methacrylsilane sizes. Particular preference is given to an epoxysilane size.

The fillers can be added in an amount of up to 40% by weight, based on the amount of polycarbonate. Preference is given to from 2.0% by weight to 40.0% by weight, particularly preferably from 3.0% by weight to 35.0% by weight.

Suitable blend partners for the thermoplastic polymers, in particular for polycarbonates, are graft polymers of vinyl monomers on graft bases such as diene rubbers or acrylate rubbers. Graft polymers B are preferably those composed of B.1 from 5% by weight to 95% by weight, preferably from 30% by weight to 90% by weight, of at least one vinyl monomer on B.2 from 95% by weight to 5% by weight, preferably from 70% by weight to 10% by weight, of one or more graft bases having glass transition temperatures of <10° C., preferably <0° C., particularly preferably <−20° C. The graft base B.2 generally has an average particle size (d50) of from 0.05 μm to 10 μm, preferably from 0.1 μm to 5 μm, particularly preferably from 0.2 μm to 1 μm. Monomers B.1 are preferably mixtures of B.1.1 from 50 to 99 parts by weight of vinylaromatics and/or ring-substituted vinylaromatics, (e.g. styrene, *-methylstyrene, p-methylstyrene, p-chlorostyrene) and/or (C1-C8)-alkyl methacrylates (e.g. methyl methacrylate, ethyl methacrylate) and B.1.2 from 1 μm to 50 parts by weight of vinyl cyanides (unsaturated nitriles such as acrylonitrile and methacrylonitrile) and/or (C1-C8)-alkyl (meth)acrylates, e.g. methyl methacrylate, n-butyl acrylate, t-butyl acrylate, and/or derivates (e.g. anhydrides and imides) of unsaturated carboxylic acids, for example maleic anhydride and N-phenylmaleinimide. Preferred monomers B.1.1 are selected from at least one of the monomers styrene, *-methylstyrene and methyl methacrylate, while preferred monomers B.1.2 are selected from at least one of the monomers acrylonitrile, maleic anhydride and methyl methacrylate. Particular preference is given to the monomers styrene as B.1.1 and acrylonitrile as B.1.2.

Graft bases B.2 suitable for the graft polymers B are, for example, diene rubbers, EP(D)M rubbers, i.e. those based on ethylene/propylene and optionally diene, acrylate, polyurethane, silicone, chloroprene and ethylene/vinyl acetate rubbers. Preferred graft bases B.2 are diene rubbers, for example those based on butadiene and isoprene, or mixtures of diene rubbers or copolymers of diene rubbers or mixtures thereof with further copolymerizable monomers (e.g. as per B.1.1 and B. 1.2), with the proviso that the glass transition temperature of the graft base B.2 is below 10° C., preferably <0° C., particularly preferably <10° C. Particular preference is given to pure polybutadiene rubber.

Particularly preferred polymers B are, for example, ABS polymers (emulsion, bulk and suspension ABS), as are described, for example, in DE 2 035 390 A1 or in DE 2 248 242 A1 or in Ullmanns, Enzyklopädie der Technischen Chemie, vol. 19 (1980), pp. 280 ff. The gel content of the graft base B.2 is at least 30% by weight, preferably at least 40% by weight (measured in toluene). The graft copolymers B are prepared by free-radical polymerization, e.g. by emulsion, suspension, solution or bulk polymerization, preferably by emulsion or bulk polymerization. Since, as is known, the graft monomers are not necessarily grafted completely onto the graft base during the grafting reaction, the term graft polymers B also encompasses those products which are obtained by (co)polymerization of the graft monomers in the presence of the graft base and are obtained concomitantly in the work-up. The polymer compositions can optionally contain further customary polymer additives such as the antioxidants, heat stabilizers, mold release agents, optical brighteners, UV absorbers and light scattering agents described in EP 0 839 623 A1, WO 96 15102 A1, EP 0 500 496 A1 or “Plastics Additives Handbook”, Hans Zweifel, 5th edition 2000, Hanser Verlag, Munich) in the amounts customary for the respective thermoplastics.

Suitable UV stabilizers are benzotriazoles, triazines, benzophenones and/or arylated cyanoacrylates. Particularly suitable UV absorbers are hydroxybenzotriazoles such as 2-(3′,5′-bis(1,1-dimethylbenzyl)-2′-hydroxyphenyl)benzotriazole (Tinuvin@ 234, BASF SE, Ludwigshafen), 2-(2′-hydroxy-5′-(tert-octyl)phenyl)benzotriazole (Tinuvin® 329, BASF SE, Ludwigshafen), 2-(2′-hydroxy-3′-(2-butyl)-5′-(tert-butyl)phenyl)benzotriazole (Tinuvin® 350, BASF SE, Ludwigshafen), bis(3-(2H-benzotriazolyl)-2-hydroxy-5-tert-octyl)methane (Tinuvin® 360, BASF SE, Ludwigshafen), 2-(4,6-diphenyl-1,3,5-triazin-2-yl)-5-(hexyloxy)phenol (Tinuvin® 1577, BASF SE, Ludwigshafen), and also the bnzophenones 2,4-dihydroxybenzophenone (Chimasorb® 22, BASF SE, Ludwigshafen) and 2-hydroxy-4-(octyloxy)benzophenone (Chimasorb® 81, BASF SE, Ludwigshafen), 2-propenoic acid, 2-cyano-3,3-biphenyl, 2,2-bis[[(2-cyano-1-oxo-3,3-diphenyl-2-propenyl)oxy]methyl]-1,3-propanediyl ester (9CI) (Uvinul® 3030, BASF SE, Ludwigshafen), 2-[2-hydroxy-4-(2-ethylhexyl)oxy]phenyl-4,6-di(4-phenyl)phenyl-1,3,5-triazine (Tinuvin® 1600, BASF SE, Ludwigshafen) or tetraethyl 2,2′-(1,4-phenylenedimethylidene)bismalonate (Hostavin® B-Cap, Clariant AG). The composition of the thermoplastic polymers can contain UV absorbers in an amount of usually from 0 to 10% by weight, preferably from 0.001% by weight to 7.000% by weight, particularly preferably from 0.001% by weight to 5.000% by weight, based on the total composition. The compositions of the thermoplastic polymers are prepared using conventional incorporation processes by combining, mixing and homogenizing the individual constituents, with, in particular, the homogenization preferably taking place in the melt under the action of shear forces. The combining and mixing is optionally carried out using powder premixes before the melt homogenization.

The thermoplastically processible polymer can be processed to give shaped bodies in the form of films or plates. The film or the plate can have one or more layers and consist of various thermoplastics or the same thermoplastics, e.g. polycarbonate/PMMA, polycarbonate/PVDF or polycarbonate/PTFE or else polycarbonate/polycarbonate.

The thermoplastically processible polymer can, for example, be shaped by injection molding or extrusion. The use of one or more side extruders and a multichannel die or optionally suitable melt adapters upstream of a slit die allows thermoplastic melts of different compositions to be placed on top of one another and multilayer plates or films thus to be produced (for coextrusion, see, for example, EP-A 0 110 221, EP-A 0 110 238 and EP-A 0 716 919, for details of the adapter and die processes see Johannaber/Ast: “Kunststoff-Maschinenfiihrer”, Hanser Verlag, 2000 and in Gesellschaft KunststoflRechnik: “Koextrudierte Folien und Platten: Zukunftsperspektiven, Anforderungen, Anlagen und Herstellung, Qualitätssicherung”, VDI-Verlag, 1990). For coextrusion, preference is given to using polycarbonates and poly(meth) acrylates. Particular preference is given to using polycarbonates.

The film can be molded and back-injected with further thermoplastics from among the abovementioned thermoplastics (film insert molding (FIM)). Plates can be thermoformed or processed by means of drape forming or bent cold. Shaping by means of injection molding processes is also possible. These processes are known to those skilled in the art. The thickness of the film or plate has to be such that sufficient stiffness of the component is ensured. In the case of a film, this can be reinforced by back-injection in order to ensure sufficient stiffness.

The total thickness of the shaped body produced from the thermoplastically processible polymer, i.e. including a possible back-injection or coextrusion layers, is generally from 0.1 mm to 15 mm. The thickness of the shaped bodies is preferably from 0.8 mm to 10 mm. In particular, the thicknesses indicated are based on the total shaped body thickness when using polycarbonate as shaped body material including a possible back-injection or coextrusion layers.

### Plasma-Enhanced Chemical Vapor Deposition

For the purposes of the invention, a plasma is a gas whose constituents have been partially or completely “broken up” into ions and electrons. This means that a plasma contains free charge carriers. A low-pressure plasma is a plasma in which the pressure is considerably lower than the earth's atmospheric pressure. Low-pressure plasmas are among nonthermal plasmas, i.e. the individual constituents of the plasma (ions, electrons, uncharged particles) are not in thermal equilibrium with one another. Typical industrial low-pressure plasmas are operated in the pressure range below 100 mbar, i.e. at pressures which are a factor of 10 lower than normal atmospheric pressure. In industrial low-pressure plasmas, electron temperatures of some electron volts (plurality of 10 000 K) are attained by selective excitation of the electrons, while the temperature of the neutral gas is only a little above room temperature. As a result, thermally sensitive materials such as polymers can also be processed by means of low-pressure plasmas. The introduction of the plasma with the workpiece takes place simply by contacting.

Methods which are suitable in the context of this patent application for producing an industrial plasma are those which are ignited by means of an electric discharge at a reduced pressure compared to atmospheric pressure of 1013 mbar using a DC voltage, high-frequency excitation or microwave excitation. These processes are known under the names low-pressure or low-temperature plasma in the prior art.

In the low-pressure plasma process, the workpiece to be treated is present in a vacuum chamber which is evacuable by means of pumps.

This vacuum chamber encloses at least one electrode when the plasma is excited by electrical excitation by means of a DC voltage or by means of high-frequency fields. As excitation frequency, it is possible to employ, for example: 13.56 MHz, 27.12 MHz, or preferably 2.45 GHz. In the preferred case of excitation being effected by means of microwave radiation, it would be possible, for example, for there to be a region which is permeable to microwave radiation and through which the microwave radiation is injected into the chamber to be present at a place on the chamber wall. Another preferred possibility is to inject the microwave power along a microwave-permeable tube, for example a fused silica tube. Such an arrangement is called Duo-Plasmaline (developed at the IGVP (formerly IPF), University of Stuttgart (E. Raüchle, Lecture at: “Third International Workshop on microwave Discharges: Fundamentals and Applications”, Abbaye de Fontevraud, France, Apr. 20-25, 1997; W. Petasch et al. “Duo-Plasmaline—A linearly extended homogenous low pressure plasma source”, Surface and Coatings Technology 93 (1997), 112-118), commercially available from, for example, Muegge Electronic GmbH, Reichelsheim, Germany). These microwave sources are typically operated by means of two 2.45 GHz magnetrons. The plasma then burns along the tubes and can thus easily extend onto large workpieces.

For the purposes of the invention, the term plasma polymerization is used synonymously with plasma-enhanced chemical vapor deposition (PECVD). Plasma polymerization is, for example, defined in “G. Benz: Plasmapolymerisation: Überblick und Anwendung als Korrosions-und Zerkratzungsschutzschichten. VDI-Verlag GmbH Düsseldorf, 1989” or in “Vakuumbeschichtung vol. 2—Verfahren, H. Frey, VDI-Verlag Düsseldorf 1995”.

Here, precursor compounds (precursors) in vapor form are firstly activated by a plasma in the vacuum chamber. The activation forms ionized particles and first molecular fragments in the form of clusters or chains are formed in the gas phase. The subsequent condensation of these fragments on the substrate surface then brings about, under the action of substrate temperature, electron bombardment and ion bombardment, the polymerization and thus the formation of a closed layer.

Layer-forming precursors are, for example, silanes or siloxanes which are introduced in vapor form into the vacuum chamber and are oxidized by means of an O₂ plasma to form SiOₓ or to form carbon-containing SiOₓC_{y}H_{z} which are deposited as vitreous layer on the substrate. The components such as carbon and hydrogen which are also present in the precursors partly react to form carbon-containing gases and also water. The hardness, the E modulus, the refractive index, the chemical composition and the morphology of the layers can be set via the ratio of the concentration of precursors to the oxygen gas. Low oxygen concentrations and high carbon concentrations tend to lead to tough layers, while high oxygen concentrations and low carbon concentrations produce hard vitreous layers.

In the case of deposition of a plurality of successive layers, the vacuum in the coating chamber can be interrupted or else not interrupted. In a preferred embodiment, the vacuum in the vacuum chamber is not interrupted between the coating steps.

### Barrier Layer

A bonding barrier layer is deposited on the thermoplastic support material by plasma-enhanced chemical vapor deposition of precursors. The barrier layer has the task of preventing diffusion of constituents from the thermoplastic support material. Furthermore, it is a task of the barrier layer to protect the thermoplastic material against external influences such as air or moisture or to reduce the influence of these on the thermoplastic support material. Furthermore, the barrier layer has to prevent direct contact of the thermoplastic support material with the UV-absorbing layer, since, depending on the embodiment, the UV-absorbing layer has a certain photocatalytic activity which can lead to partial degradation of the thermoplastic support layer. This results in a reduced aging resistance.

Suitable silicon-based precursors are, for example, selected from the group consisting of hexamethyldisiloxane (HMDSO), octamethyltrisiloxane, decamethyltetrasiloxane, dodecamethylpentasiloxane, hexamethylcyclotrisiloxane, octamethylcyclotetrasiloxane (D4), decamethylcyclopentasiloxane, dodecamethylcyclohexasiloxane, tetramethylcyclotetrasiloxane, tetraethoxysilane, tetramethyldisiloxane (TMDSO), trimethoxymethylsilane, dimethyldimethoxysilane, hexamethyldisilazane, triethoxyphenylsiloxane or vinyltrimethylsilane.

Preference is given to precursors from the group consisting of hexamethyldisiloxane, octamethylcyclotetrasiloxane (D4), tetramethylcyclotetrasiloxane, tetraethoxysilane (TEOS), tetramethyldisiloxane, trimethoxymethylsilane, dimethyldimethoxysilane, hexamethyldisilazane, triethoxyphenylsiloxane or vinylsilane. Particular preference is given to using TEOS, hexamethyldisiloxane (HMDSO) and octamethylcyclotetrasiloxane (D4).

The halides of the elements Ti, Zr, Hf, V, Nb, Ta, Mo, W, Re, Os, B, Al, C, Si, Ge, Sn, As and Sb are also suitable as precursor for the deposition of layers by plasma-enhanced chemical vapor deposition.

Examples of halides as mentioned above are trichloroethylsilane, trichloroboride, tetrachlorotitanate, trifluoroboride, tetrachlorosilane, trichloroaluminate and zirconium(IV) chloride. Preferred halides are the chlorides of the abovementioned elements, with particular preference being given to tetrachlorotitanate, tetrachlorosilane and trichloroethylsilane.

The carbonyls of the elements V, Cr, Mo, W, Mn, Tc, Re, Fe, Ru, Os, Co and Ni are also suitable as precursor for the deposition of layers by chemical vapor deposition.

The hydrides of the elements B, C, Si, Ge, Sn, N, P, As and Sb are also suitable as precursor for the deposition of layers by chemical vapor deposition.

The alkyls of the elements Ti, Zr, Hf, Zn, Cd, Hg, Al, Ga, In, C, Si, Ge, Sn, Pb, N, P, As, Be, Hg, Mg, Bi, Se, Te and Sb are also suitable as precursor for the deposition of layers by plasma-enhanced chemical vapor deposition. Examples of alkyls as mentioned above are diisobutylaluminum hydride, triethyl aluminate, triisobutyl aluminate, trimethyl aluminate, triethylantimony, trimethylantimony, triisopropylantimony, stibane (SbH₃), triethylarsenic, trimethylarsenic, monoethylarsane, tert-butylarsane, arsine (AsH₃), diethylberyllium, trimethylbismuth, dimethylcadmium, diethylcadmium, allylmethylcadmium, triethylgallium, trimethylgallium, tetramethylgermanium, tetraethylgermanium, isobutylgermanium, dimethylaminogermanium trichloride, triethylindium, trimethylindium, diisopmpylmethylindium, ethyldimethylindium, bis(cyclopentadienyl)magnesium, dimethylmercury, triethylphosphine, trimethylphosphine, diethyl selenide, dimethyl selenide, diisopropyl selenide, triethylsilane, diethyl telluride, dimethyl telluride, diisopropyl telluride, tetraethyltin, tetramethyltin, diethylzinc, diemethylzinc, trisopropyl titanate and tetraisopropyl titanate. Preference is given to the alkyls of the elements titanium and zinc.

Apart from the halides, carbonyls, hydrides and also alkyls, the alkoxides, diketonates, cyclopentadienyl compounds, amido complexes and PF3 complexes of the abovementioned elements are suitable as precursor for the deposition of layers by plasma-enhanced chemical vapor deposition. Preference is given to using the elements Cu, Pd, Pt, Ag, Au, Co, Rh and Ir as cyclopentadienyl compound, β-diketonate and with a chelating agent, for example 1,1,1,5,5,5-hexafluoracetyleneacetone, 2,2-dimethyl-6,6,7,7,8,8,8-heptafluoro-3,5-octanedione, acetylacetone, 2,2,6,6-tetramethylheptane-3,5-dione and 1,1,1-trifluoro-2,4-pentanedione.

Further suitable precursors for the plasma-enhanced chemical vapor deposition are acetylene, benzene, hexafluorobenzene, styrene, ethylene, tetrafluoroethylene, cyclohexane, oxirane, acrylic acid, propionic acid, vinyl acetate, methyl acrylate, hexamethyldisilane, tetramethyldisilane and divinyltetramethyldisiloxane.

Further suitable precursors for the chemical vapor deposition are vinylferrocene, 1,3,5-trichlorobenzene, chlorobenzene, styrene, ferrocene, picolin, naphthalene, pentamethylbenzene, nitrotoluene, acrylonitrile, diphenyl selenide, p-toluidine, p-xylene, N,N-dimethyl-p-toluidine, toluene, aniline, diphenylmercury, hexamethylbenzene, malononitrile, tetracyanoethylene, thiopene, benzeneselenol, tetrafluoroethylene, ethylene, N-nitrosodiphenylamine, thianthrene, acetylene, N-nitrosopiperidine, dicyanoketene ethyl acetal, cyamelurin, 1,2,4-trichlorobenzene, propane, thiourea, thioacetamide, N-nitrosodiethylamine, hexa-n-butyl(di)tin and triphenylarsine.

As reactive gas, use is made of, for example, oxygen, air, dinitrogen oxide, nitrogen oxides, nitrogen, hydrogen, carbon monoxide, methane, water, low molecular weight hydrocarbons and ammonia. Preference is given to using oxygen, dinitrogen oxide and nitrogen.

A carrier gas can be used in addition to the reactive gas. As carrier gas, use is made of helium, neon, argon, krypton, xenon, nitrogen and carbon dioxide. Preference is given to using argon, nitrogen and carbon dioxide.

In a preferred embodiment of the barrier layer, the barrier layer consists, depending on the carrier gas and reactive gas used, of an oxide, mixed oxide, nitride or oxynitride of the abovementioned elements or mixtures thereof.

In a particularly preferred embodiment of the present invention, the barrier layer consists of silicon dioxide or carbon-containing SiO_{X}C_{y}H_{z}.

In one embodiment of the present invention, the gas flows of the precursors and of the reactive gas are kept at a constant ratio to one another, with the gas flow of the reactive gas being greater than the gas flow of the precursor.

In a further embodiment of the present invention, the oxygen content, the nitrogen content and/or the carbon content in the resulting barrier layer has a gradient or a step-like change in content, preferably so that the oxygen content or the nitrogen content is smallest in the vicinity of the thermoplastic support and the carbon content is highest.

In a further embodiment of the present invention, the oxygen content, the nitrogen content and/or the carbon content in the resulting barrier layer goes through a maximum or a minimum.

In a further embodiment of the present invention, the resulting barrier layer is free of organic constituents such as hydrocarbon radicals at the side facing away from the thermoplastic support.

The thickness of the barrier layer is less than 5 μm, preferably less than 3 μm, particularly preferably less than 1.5 μm.

The plasma power for depositing the barrier layer is, in a further embodiment of the present invention, from 2×1 to 2×3 kW, based on an array arrangement of 4 Duo-Plasmalines having a length of 28 cm (power density=1786 W/m−5357 W/m) and a pressure range of 0.1-1.5 mbar, with the power being introduced in the continuous wave mode. The minimum power of the introduction of microwaves is determined by the condition that, for a given Duo-Plasmaline configuration and at given gas flows and also pressures, the plasma ignites and spreads homogeneously around the Duo-Plasmalines.

In a further embodiment of the present invention, the time for deposition of the barrier layer in a thickness of 1 μm is preferably less than 20 s, particularly preferably less than 15 s and very particularly preferably less than 10 s.

### UV Protection Layer

For the deposition of the UV protection layer by chemical vapor deposition, metal compounds whose metals as such or together with silicon form UV-absorbing oxides, oxynitrides or nitrides and have a sufficiently high vapor pressure are used as precursors. Examples are carbonyls, metallocenes, alkyls, nitrates, acetylacetonates, acetates or alkoxy compounds of the metals cerium, zinc, titanium, vanadium, yttrium, indium, iron, tin and zirconium. It can be necessary here to add nitrogen or noble gases such as argon to the oxygen plasma.

Preference is given to using diethylzinc, zinc acetate, triisopropyl titanate, tetraisopropyl titanate, cerium β-diketonate and cerium ammonium nitrate as precursors.

In one embodiment of the present invention, the UV protection layers preferably consist of zinc oxide, titanium dioxide, cerium oxide or vanadium pentoxide, very particularly preferably of zinc oxide, titanium dioxide and cerium oxide.

In a further embodiment of the present invention, a UV protection layer consisting of at least two metals is deposited as mixed oxide. Examples of such mixed oxides are indium-tin oxide (ITO), antimony-tin oxide (ATO), aluminum zinc oxide (AZO) and indium zinc oxide (IZO) and also mixed oxides of the abovementioned metals.

The thickness of the UV protection layer in the absence of further UV-absorbing layers is selected so that the optical density of the layer at a wavelength of 340 nm is preferably >2, particularly preferably >2.5. The preferred thickness is accordingly in the range from 50 nm to 5 μm, particularly preferably from 100 nm to 2 μm and very particularly preferably from 0.4 μm to 1.5 μm.

In a further embodiment of the present invention, the UV protection layer is interrupted by other layers, for example by an intermediate layer, as a result of which the layer voltage is controlled.

To form a very stable UV protection effect, the Me_{y}/Oₓ ratio is selected so as to be greater than 1, preferably greater than 1.2.

The plasma power for deposition of the UV protection layer is, in a further embodiment of the present invention, 2×1 kW-2×3 kW, based on an array arrangement of 4 Duo-Plasmalines having a length of 28 cm (power density=1786 W/m−5357 W/m) and a pressure range of 0.1-1.5 mbar, with this power being introduced in the continuous wave mode. The minimum power of the introduction of microwaves is determined by the condition that, for a given Duo-Plasmaline configuration and at given gas flows and pressures, the plasma ignites and spreads homogeneously around the Duo-Plasmalines.

### Covering Layer

The task of the covering layer is to protect the UV protection layer against external influences such as moisture and media. A further task is to provide a surface which offers scratch resistance and abrasion resistance and also a defect-free surface which is free of flaws and inclusions.

Suitable silicon-based precursors are, for example, selected from the group consisting of hexamethyldisiloxane (HMDSO), octamethyltrisiloxane, decamethyltetrasiloxane, dodecamethylpentasiloxane, hexamethylcyclotrisiloxane, octamethylcyclotetrasiloxane (D4), decamethylcyclopentasiloxane, dodecamethylcyclohexasiloxane, tetramethylcyclotetrasiloxane, tetraethoxysilane (TEOS), tetramethyldisiloxane (TMDSO), trimethoxymethylsilane, dimethyldimethoxysilane, hexamethyldisilazane, triethoxyphenylsiloxane or vinyltrimethylsilane.

Preference is given to precursors from the group consisting of hexamethyldisiloxane, octamethylcyclotetrasiloxane, tetramethylcyclotetrasiloxane, tetraethoxysilane (TEOS), tetramethyldisiloxane, trimethoxymethylsilane, dimethyldimethoxysilane, hexamethyldisilazane, triethoxyphenylsiloxane or vinylsilane. Particular preference is given to using TEOS, hexamethyldisiloxane (HMDSO) and octamethylcyclotetrasiloxane (D4).

The halides of the elements Ti, Zr, Hf, V, Nb, Ta, Mo, W, Re, Os, B, Al, C, Si, Ge, Sn, As and Sb are also suitable as precursor for the deposition of layers by chemical vapor deposition. Examples of halides as mentioned above are trichloroethylsilane, trichloroboride, tetrachlorotitanate, trifluoroboride, tetrachlorosilane, trichloroaluminate and zirconium(IV) chloride. Preferred halides are the chlorides of the abovementioned elements, with particular preference being given to tetrachlorotitanate, tetrachlorosilane and trichloroethylsilane.

The carbonyls of the elements V, Cr, Mo, W, Mn, Tc, Re, Fe, Ru, Os, Co and Ni are also suitable as precursor for the deposition of layers by chemical vapor deposition.

The hydrides of the elements B, C, Si, Ge, Sn, N, P, As and Sb are also suitable as precursor for the deposition of layers by chemical vapor deposition.

The alkyls of the elements Ti, Zr, Hf, Zn, Cd, Hg, Al, Ga, In, C, Si, Ge, Sn, Pb, N, P, As, Be, Hg, Mg, Bi, Se, Te and Sb are also suitable as precursor for the deposition of layers by chemical vapor deposition. Examples of alkyls as mentioned above are diisobutylaluminum hydride, triethyl aluminate, triisobutyl aluminate, trimethyl aluminate, triethylantimony, trimethylantimony, triisopropylantimony, stibane (SbH₃), triethylarsene, trimethylarsene, monoethylarsane, tertiarybutylarsane, arsine (AsH₃), diethylberyllium, trimethylbismuth, dimethylcadmium, diethylcadmium, allylmethylcadmium, triethylgallium, trimethylgallium, tetramethylgermanium, tetraethylgermanium, isobutylgermanium, dimethylaminogermanium trichloride, triethylindium, trimethylindium, diisopropylmethylindium, ethyldimethylindium, bis(cyclopentadienyl)magnesium, dimethylmercury, triethylphosphine, trimethylphosphine, diethyl selenide, dimethyl selenide, diisopropyl selenide, triethylsilane, diethyl telluride, dimethyl telluride, diisopropyl telluride, tetraethyltin, tetramethyltin, diethylzinc, dimethylzinc, trisopropyl titanate and tetraisopropyl titanate. Preference is given to the alkyls of the elements titanium, silicon and zinc.

Apart from the halides, carbonyls, hydrides and alkyls, the alkoxides, diketonates, cyclopentadienyl compounds, amino complexes and PF3 complexes of the abovementioned elements are suitable as precursor for the deposition of layers by chemical vapor deposition. Preference is given to using the elements Cu, Pd, Pt, Ag, Au, Co, Rh and Ir as cyclopentadienyl compound, β-diketonate and with a chelating agent, for example 1,1,1,5,5,5-hexafluoroacetyleneacetone, 2,2-dimethyl-6,6,7,7,8,8,8-heptafluoro-3,5-octanedione, acetylacetone, 2,2,6,6-tetramethylheptane-3,5-dione and 1,1,1-trifluoro-2,4-pentanedione.

Further suitable precursors for the chemical vapor deposition are acetylene, benzene, hexafluorobenzene, styrene, ethylene, tetrafluoroethylene, cyclohexane, oxirane, acrylic acid, propionic acid, vinyl acetate, methyl acrylate, hexamethyldisilane, tetramethyldisilane and divinyltetramethyldisiloxane.

Further suitable precursors for the chemical vapor deposition are vinylferrocene, 1,3,5-trichlorobenzene, chlorobenzene, styrene, ferrocene, picoline, naphthalene, pentamethylbenzene, nitrotoluene, acrylonitrile, diphenyl selenide, p-toluidine, p-xylene, N,N-dimethyl-p-toluidine, toluene, aniline, diphenylmercury, hexamethylbenzene, malononitrile, tetracyanethylene, thiopene, benzeneselenol, tetrafluoroethylene, ethylene, N-nitrosodiphenylamine, thianthrene, acetylene, N-nitrosopiperidine, dicyanoketene ethyl acetal, cyamelurin, 1,2,4-trichlorobenzene, propane, thiourea, thioacetamide, N-nitrosodiethylamine, hexa-n-butyl(di)tin and triphenylarsine.

As reactive gas, use is made of oxygen, air, dinitrogen oxide, nitrogen oxides, nitrogen, hydrogen, carbon dioxide, methane, water, low molecular weight hydrocarbons and ammonia. Preference is given to using oxygen, dinitrogen oxide and nitrogen.

In addition to the reactive gas, it is possible to use a carrier gas. As carrier gas, use is made of helium, neon, argon, krypton, xenon, nitrogen and carbon dioxide. Preference is given to using argon, nitrogen and carbon dioxide.

In a preferred embodiment of the covering layer, the covering layer consists, depending on the carrier gas and reactive gas used, of an oxide, mixed oxide, nitride or oxynitride of the abovementioned elements or mixtures thereof.

In a particularly preferred embodiment of the present invention, the covering layer consists of silicon dioxide or carbon-containing SiOₓC_{y}H_{z}.

In a preferred embodiment of the present invention, the oxygen content, the nitrogen content and/or the carbon content in the resulting covering layer have a continuous gradient and no step-like change in content, preferably so that the oxygen content or nitrogen content is lowest in the vicinity of the UV protection layer and the carbon content is highest. The oxygen content of the covering layer near the UV light-absorbing layer is lower than on the opposite side of the covering layer and the carbon content close to the UV light-absorbing layer is higher than on the opposite side of the covering layer.

In a preferred embodiment of the present invention, the oxygen content, the nitrogen content and/or the carbon content in the resulting covering layer goes through a maximum or minimum.

In a further embodiment of the present invention, the resulting covering layer is free of organic constituents such as hydrocarbon radicals at the side facing away from the UV protection layer.

In a further embodiment, the covering layer has a haze increase of less than 10%, preferably less than 6% and particularly preferably less than 3%, after stressing in accordance with ASTM D 1044 by means of a Taber Abraser model 5131 after 1000 cycles.

The thickness of the covering layer is preferably in the range from 1 μm to 15 μm, particularly preferably from 2 μm to 12 μm and very particularly preferably from 3 μm to 10 μm.

The plasma power for deposition of the barrier layer is, in a further embodiment of the present invention, from 2×1 to 2×3 kW, based on an array arrangement of 4 Duo-Plasmalines having a length of 28 cm (power density=1786 W/m−5357 W/m) and a pressure range of 0.1-1.5 mbar, with this being introduced in the continuous wave mode. The minimum power of the introduction of microwaves is determined by the condition that, for a given Duo-Plasmaline configuration and at given gas flows and pressures, the plasma ignites and spreads homogeneously around the Duo-Plasmalines.

### Further Functional Layers

One or more layers can be deposited on the covering layer by chemical physical vapor deposition.

As functional layer, it is possible to use, inter alia, nonconducting oxides {TiO₂, ZrO₂, ZrSiₓOᵣ, HfO₂, HfSiₓO_{y}, Ln₂O₃, LnSiₓO_{y}, LnAlO₃, SiO₂, Ta₂O₅ and Nb₂O₅}, ferroelectric oxides {SrTiO₃, (Ba,Sr)TiO₃, Pb(Zr,Ti)O₃, SrBi₂(TaₓNb₁₋ₓ)₂O₉, Bi₄Ti₃O₁₂, Pb(Sc,Ta)O₃ and Pb(Mg,Nb)O₃}, ferrites {(Ni,Zn)Fe₂O₄, (Mn,Zn)Fe₂O₄}, superconductors {YBa₂Cu₂O₇₋ₓ, Bi—Sr—Ca—Cu—O}, conductive oxides {(La,Sr)CoO₃, (La,Mn)O₃, RuO₂, SrRuO₃}, conductive oxides having a low emission {F-doped SnO₂ and Sn-doped In₂O₃}, electrochromic or photochromic oxides {WO₃ and MoO₃}, thermochromic oxides {VO₂}, self-cleaning layers {TiO₂}, metal layers {Al, W, Cu, Au, Ag, Pt, Pd, Ni, Ti, Cr, Mo, Ru, Ta}, metal nitrides {AlN, Si₃N₄, TiN, ZrN, HfN, TaN, NbN, WN, MoN, BN} and metal carbides {TiC, ZrC, HfC, Cr₇C₃, Cr₃C₂, WC, W₂C, W₃C, V carbide, Ta, Nb carbide, SiC, GeC, BC}.

In a further embodiment of the present invention, the functional layer is present in the multilayer structure.

In a further embodiment of the present invention, the covering layer is dispensed with when a further functional layer is present.

### Preferred Structures and Properties of the Multilayer Structure

In a further embodiment, the multilayer structure has an initial haze determined in accordance with ASTM D 1003 of less than 3%, preferably less than 2.5% and particularly preferably less than 2.0%.

In a further embodiment, the multilayer structure has an initial yellowness index determined in accordance with ASTM E 313 of less than 3.0, preferably less than 2.5 and particularly preferably less than 2.0.

In a further embodiment, the multilayer structure does not display any delamination in adhesion tests in accordance with ASTM D 3359 and ISO 2409.

In a further embodiment, the multilayer structure has a haze determined in accordance with ASTM D 1003 after aging in accordance with ASTM G155 after 4000 hours or after an energy input of 10.8 MJ/m² at 340 nm of less than 7.0%, preferably less than 5.0% and particularly preferably less than 4.0%.

In a further embodiment, the multilayer structure has a yellowness index determined in accordance with ASTM E 313 after aging in accordance with ASTM G155 after 4000 hours or after an energy input of 10.8 MJ/m² at 340 nm of less than 7.5, preferably less than 6.5 and particularly preferably less than 5.5.

Furthermore, no cracks in the structure and no delamination of the layers from the thermoplastic support occur after aging in accordance with ASTM G155 after 4000 hours or after an energy input of 10.8 MJ/m² at 340 nm.

In a preferred embodiment of the present invention, the total thickness of the individual layers on the thermoplastic support is less than 20 μm, particularly preferably less than 15 μm and very particularly preferably less than 10 μm.

In a further embodiment of the present invention, the plant utilized for deposition of the layers satisfies the condition that the ratio of pump power in m³/h to volume of the vacuum chamber in m³ is at least 10 000 l/h, preferably greater than 75 000 l/h.

In a preferred embodiment, the pressure in the vacuum chamber at maximum pump power and at maximum gas flows of precursors, carrier gases and reactive gases in the absence of the plasma required for deposition is less than 1.5 mbar, particularly preferably less than 1 mbar and very particularly preferably less than 0.5 mbar.

### EXAMPLES

The following examples illustrate the production of the multilayer structures and the in-principle structure thereof, without being restricted to the examples presented.

A linear polycarbonate based on bisphenol A having an MVR of about 9.5 g/10 min (in accordance with ISO 1133, at 300° C. and a load of 1.2 kg) which is commercially available under the name Makrolon® M2808 from Bayer MaterialScience AG was utilized as thermoplastic support.

The materials used for producing the multilayer structures are tabulated below.

| Materials | CAS number | Manufacturer |
|---|---|---|
| HMDSO - hexamethyldisiloxane | 107-46-0 | Aldrich |
| DEZ - diethylzinc | 557-20-0 | Aldrich |
| Oxygen | 7782-44-7 | Linde |
| Aluminum sheet | | Commercial |

### Description of the “Plasmodul” Coating Plant

The “Plasmodul” is a vacuum vessel having a modular structure for plasma-technology surface treatment and layer deposition at low pressure. The Plasmodul is made up of various modules, of which each has a particular purpose in the coating process.

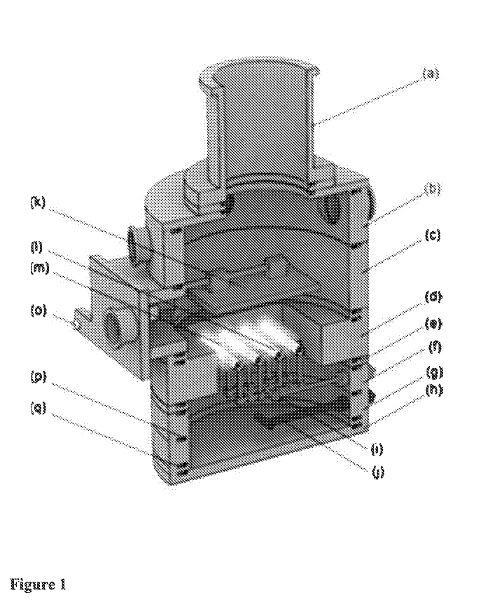

FIG. 1 shows a sketch of the “Plasmodul” coating reactor:

(a) connection for the vacuum pump, (b) diagnostic module, (c) substrate holder module, (d) source module, (e) spacer ring, (f) module for precursor gas introduction, (g) module for O₂ gas introduction, (h) bottom, (i) gas outlet for the precursor, (j) gas outlet O₂, (k) substrate holder, (l) array made up of 4 Duo-Plasmalines, (m) plasma zone, (o) rail guide for the substrate holder (p) sealing ring, (q) microwave shielding.

The plasma source, which consists of an array of four Duo-Plasmalines (l), is located in the source module (d). On the outside of the module, there are connections for the supply of microwaves to the plasma source. Under the source module (d), there are the modules for precursor gas introduction (f) and for oxygen gas introduction (g) and also the bottom (h). The introduction of the process gases thus occurs spatially separately from one another. Connections for the respective gas feed lines are installed on the outside of the precursor gas introduction module and oxygen gas introduction module. The substrate holder module (c), the diagnostic module (b) and the connection for the vacuum pump (a) are installed above the source module (d). The distances between the individual modules can be altered by means of spacer rings (e).

The gas introduction facility for the precursor (i) is made up of tubes and has 16 gas outlets, the ends of which are located centrally between the Duo-Plasmalines. To ensure homogeneous distribution of gas over the gas outlets, the feed lines are constructed fractally. The gas introduction facility for oxygen (j) consists of a tube which divides horizontally into two parts in the middle of the Plasmodul. The oxygen firstly becomes homogeneously distributed in the lower region of the chamber and then flows upward in the direction of the vacuum pump. The oxygen has to pass through the plasma zone (m) formed around the Duo-Plasmalines (l). The substrate holder (k) consists of a copper plate which has the size 17 cm*17 cm and to the underside of which the substrates can be fastened by means of clips. The substrate holder can be pulled out by means of a rail guide (o) for loading and unloading. The diagnostic module (b) has a plurality of connection flanges for the installation of diagnostics and measuring instruments. A pressure gauge for measuring the pressure and a valve for ventilating the plant are arranged on the diagnostic module. The individual modules have a sealing surface on the underside and two grooves on the upper side for the insertion of sealing rings (p) for scaling the vacuum between the modules and elastic metal wire braid rings (q) for shielding the microwaves.

The total height of the Plasmodul is about 58 cm and the diameter is 35 cm.

A vaporizer system for HMDSO having a throughput of from 9 to 450 g/h and a pump stand which has a throughput of 2000 m³/h and consists of a combination of rotary piston pump with a screw prevacuum pump is used for the plant periphery. Oxygen is available at up to 25 slm and the plasma can be operated at up to 2×3 kW=6 kW continuous wave (cw) or 2×10 kW=20 kW pulsed microwave power.

### Description of the Deposition of the Layers

### Preparation and Switching-on the Plant:

The surface of the thermoplastic support material is freed of dust particles and other impurities by suitable means, e.g. deionization of the surface or blow-off with oil-free compressed air.

For installation of the thermoplastic support material in the coating chamber, the plant is in the switched-off state, i.e. the coating chamber is vented, the vacuum pump and the microwave supply are switched off and all shut-off valves for the supply of gas are closed. The thermoplastic support material is installed in the substrate holder with the side to be coated facing downward by means of the clamping device. The substrate holder is subsequently moved in.

The cooling water circuit for the magnetron and the vacuum pump is activated. The vacuum pump is switched on with the butterfly valve open. The vaporizer or the heating of the precursors and also the heating of the feed lines are switched on and set to the desired value (about 70° C. for HMDSO, 20-40° C. for DEZ). The control instrument for the mass flow regulators and gauges for the precursors and the oxygen is switched on and communication with the PC is established. The grid power for microwave supply is switched on and the control software on the PC started. In the control software, the continuous wave mode (cw) is selected and set to external triggering. The cooling air supply for the Duo-Plasmalines is activated. After reaching the starting pressure of about 0.5-1.0 Pa, coating can be commenced.

### Deposition of the Layers 2 (Barrier Layer) and 4 (Covering Layer):

The precursor HMDSO (hexamethyldisiloxane) is used for deposition of the layers 2 and 4. The shut-off valves for the HMDSO and O₂ supply are opened. It is ensured that a vacuum prevails in the coating chamber and the gases do not come into contact with air. The desired gas flows are set via the control software of the mass flow regulators. The desired microwave power is set by means of the software. The desired coating time is regulated by means of a time switching clock which transmits a control signal to the microwave grid supply. After the working pressure has stabilized in the coating chamber, the microwave is activated by switching on the time switching clock and coating is commenced. The lighting of the plasma indicates that the coating process is running. After the set coating time has elapsed, the microwave is deactivated and the plasma is extinguished. The gas flows for HMDSO and O₂ are subsequently set to zero.

### Deposition of Layer 3 (UV Protection Layer):

The precursor DEZ (diethylzinc) is used for deposition of the layer 3. The shut-off valves for the DEZ and O₂ supply are opened. It has to be ensured that a vacuum prevails in the coating chamber and the gases do not come into contact with air. The desired gas flows are set via the control software of the mass flow regulators or via an adjusting valve. The desired microwave power is set by means of the software. The desired coating time is regulated by means of a time switching clock which transmits a control signal to the microwave grid supply. After the working pressure has stabilized in the coating chamber, the microwave is activated by switching on the time switching clock and coating is commenced. The lighting of the plasma indicates that the coating process is running. After the set coating time has elapsed, the microwave is deactivated and the plasma is extinguished. The gas flows for DEZ and O₂ are subsequently set to zero.

During deposition of the combinations of layers 2 to 4, the vacuum in the coating chamber is not interrupted.

Switching-off the plant and unloading of the thermoplastic support material

All shut-off valves for the introduction of gas are closed. The butterfly valve is subsequently closed and the vacuum pump is switched off. To ventilate the plant, the ventilation valve is slowly opened. After ventilation, the substrate holder is moved out and the coated specimen is taken out.

### Test Methods

The aging of the multilayer structures was carried out in accordance with ASTM G155 in an Atlas Ci 5000 Weatherometer at an irradiation intensity of 0.75 W/m²/nm at 340 nm and a dry/rain cycle of 102:18 minutes. After a given aging time, the surface was visually assessed for any damage which has occurred.

The determination of the transmission of the multilayer structures was carried out on a Lambda 900 spectrophotometer from Perkin Elmer having a photometer sphere in accordance with ISO 13468-2.

The determination of the haze of the multilayer structures was carried out in accordance with ASTM D 1003 using a Haze Gard Plus from Byk-Gardner.

The determination of the yellowness index (YI) of the multilayer structures was carried out in accordance with ASTM E 313 using a HunterLAB UltraScan Pro spectrometer.

The layer thicknesses of the individual layers of the multilayer structures were determined by means of white light interference using the measuring instrument Eta SD 30 from Eta Optik GmbH, Germany.

The strength of adhesion of the multilayer structures was determined by means of adhesive tape pull-off (adhesive tape used: 3M Scotch 610-1PK) using a grid cut (analogous to ISO 2409 or ASTM D 3359) and also by means of adhesive tape pull-off after storage for 1 hour in boiling water. Evaluation of the strength of adhesion was carried out in accordance with ISO 2409 (0 . . . no delamination; 5 . . . large-area delamination).

The coated side of the multilayer structures was treated by means of a Taber Abraser model 5131 from Erichsen in accordance with ISO 52347 or ASTM D 1044 using the CS10F wheels (generation 4; weight=500 g; 1000 cycles). Determination of the haze before and after the treatment makes it possible to calculate the A haze by forming the difference.

A measurement of the UV absorption is the optical density of the respective layer structure on the thermoplastic support at 340 nm, hereinafter referred to as OD340. This can, for example, be determined by means of a Perkin Elmer Lambda 900 spectrophotometer. The OD340 is determined from the spectral transmission T at a wavelength of 340 nm according to the following formula:

$$OD 340 = {log}_{10} ( \frac{{T}_{sub}}{{T}_{ss}} )$$

where T_{sub} is the transmission of the uncoated thermoplastic support and Tₛₛ is the transmission of the coated thermoplastic support.

### Deposition Parameters for Producing the Multilayer Structures on the Thermoplastic Support Material (Table 1)

In comparison 1, the covering layer was applied in a plurality of stages to the UV protection layer. These stages were achieved by the regulation of the oxygen flow as indicated below. In comparison 2, the oxygen flow was kept constant during deposition of the covering layer. In example 1, the oxygen flow was increased continuously during deposition of the covering layer, as a result of which an oxygen gradient is formed in the covering layer.

TABLE 1

| | Parameters for | | | | |
|---|---|---|---|---|---|
| | deposition of the | | Compar- | Compar- | |
| | layers | Unit | ison 1 | ison 2 | Example 1 |
| Layer 2 | HMDSO flow | g/h | 200 | 200 | 200 |
| | Oxygen flow | sl/min | 4.14 | 4.14 | 4.14 |
| | Power | W | 2 × 3000 | 2 × 3000 | 2 × 3000 |
| | Pulse | ms | cw | cw | cw |
| | Coating time | s | 5 | 5 | 5 |
| Layer 3 | Diethylzinc flow | g/h | 16.5 | 16.5 | 16.5 |
| | Oxygen flow | sl/min | 1.00 | 1.00 | 1.00 |
| | Power | W | 2 × 1000 | 2 × 1000 | 2 × 1000 |
| | Pulse | ms | cw | cw | cw |
| | Coating time | s | 120 | 210 | 180 |
| Layer 4 | HMDSO flow | g/h | 200 | 200 | 200 |
| | Oxygen flow | sl/min | stages: | 4.14 | Gradient: |
| | | | 0 to 1.0; | | 0 to 4.0 |
| | | | 2.5; | | |
| | | | 5.0 | | |
| | Power | W | 2 × 3000 | 2 × 3000 | 2 × 3000 |
| | Pulse | ms | cw | cw | cw |
| | Coating time | s | 3 × 10 | 25 | 25 |

TABLE 2
Results

| | | Com- | Com- | |
|---|---|---|---|---|
| Property | Unit | parison 1 | parison 2 | Example 1 |
| Thickness of layer 2 | μm | 1.0 | 1.0 | 1.0 |
| Thickness of layer 3 | μm | 0.4 | 0.7 | 0.6 |
| Thickness of layer 4 | μm | 4.0 | 5.0 | 5.0 |
| Transmission | % | 89.0 | 88.6 | 89.1 |
| OD340 | | 1.7 | 2.7 | 2.9 |
| Haze (initial) | % | 1.2 | 1.8 | 1.6 |
| Haze after 4000 h | % | 4.5 | 6.2 | 3.8 |
| Yellowness index (initial) | [ ] | 0.9 | 2.4 | 1.8 |
| Yellowness index after | [ ] | 6.5 | 6.2 | 5.0 |
| 4000 h | | | | |
| Visual evaluation | [ ] | Cracks | Cracks | No cracks |
| Δ Haze after 1000 cycles | % | 2.6 | 2.3 | 2.4 |
| (Taber Abrasion Test) | | | | |
| Strength of adhesion of | | 0 | 0 | 0 |
| layers 2 to 4 to layer 1 | | | | |
| (initial) | | | | |
| Strength of adhesion of | | 0 | 0 | 0 |
| the layers 2 to 4 to layer 1 | | | | |
| (1 h boiling test) | | | | |

It has surprisingly been found that deposition of a covering layer having a continuously changing oxygen content in the layer leads to a significantly improved aging stability compared to a constant oxygen content or oxygen content which rises in steps in the covering layer. Thus, both the increasing haze and also the increase in the yellowness index after aging are lower in example 1 than in the case of comparisons 1 and 2. Furthermore, the comparisons have cracks after aging, while the covering layer in example 1 is completely crack-free and thus intact. The abrasion test even displays, with values of less than 3% in the increasing haze, an improvement compared to wet coatings which are used nowadays and are applied by the flooding process. The optical density at 340 nm is 2.9 in example 1 and thus at a high and thus preferred level, by means of which thermoplastic support materials are adequately protected.

Determination of the stoichiometric ratios of zinc to oxygen in layer 3 was carried out by means of X-ray photoelectron spectroscopy (ESCA) on layers deposited on an aluminum sheet using the following parameters (table 3).

TABLE 3

| Parameters for | | | | | | |
|---|---|---|---|---|---|---|
| deposition of the layers | Unit | Example 2 | Example 3 | Example 4 | Example 5 | Example 6 |
| Diethylzinc flow | g/h | 34.3 | 37.6 | 37.0 | 33.7 | 34.3 |
| Oxygen flow | sl/min | 2.6 | 1.8 | 1.1 | 0.5 | 0.2 |
| Power | W | 2 × 1000 | 2 × 1000 | 2 × 1000 | 2 × 1000 | 2 × 1000 |
| Pulse | ms | cw | cw | cw | cw | cw |
| Coating time | s | 100 | 120 | 100 | 90 | 60 |
| Layer thickness | μm | 0.41 | 0.58 | 0.48 | 0.46 | 0.50 |
| Zinc/oxygen ratio | | 1.30 | 1.38 | 1.43 | 1.34 | 1.20 |

It has surprisingly been found that the stoichiometric ratio of zinc to oxygen in layer 3 is independent of the ratio of the starting gas flows of zinc and oxygen and is at a value in the range from 1.2 to 1.43. At a stoichiometric ratio of zinc to oxygen of >1, good and stable aging resistance is achieved.

1.-19. (canceled)

20. A multilayer structure containing, in the following order:
1) a thermoplastic support material,
2) a barrier layer containing silicon-based precursors,
3) a UV protection layer based on a metal oxide (Me_{y}Oₓ) having a composition of Me_{y}/Oₓ>1, preferably >1.2, where the metal oxide is selected from the group consisting of diethylzinc, zinc acetate, triisopropyl titanate, tetraisopropyl titanate, cerium β-diketonate and cerium ammonium nitrate,
4) a covering layer, where the covering layer is formed from a silicon-based precursor having an element gradient in the oxygen concentration and/or carbon or hydrocarbon concentration and the oxygen content of the covering layer close to the UV light-absorbing layer is less than on the opposite side of the covering layer and the carbon content near the UV light-absorbing layer is higher than on the opposite side of the covering layer.

21. The multilayer structure as claimed in claim 20, wherein the thermoplastic support material is selected from the group consisting of polycarbonate, copolycarbonate, polyester carbonate, polystyrene, styrene copolymers, aromatic polyesters such as polyethylene terephthalate (PET), PET-cyclohexanedimethanol copolymer (PETG), polyethylene naphthalate (PEN), polybutylene terephthalate (PBT), aliphatic polyolefins such as polypropylene or polyethylene, cyclic polyolefin, polyacrylates or copolyacrylates and polymethacrylate or copolymethacrylate e.g. polymethyl or copolymethyl methacrylates (e.g. PMMA), and copolymers with styrene such as transparent polystyrene-acrylonitrile (PSAN), thermoplastic polyurethanes, polymers based on cyclic olefins, polycarbonate blends with olefinic copolymers or graft polymers, for example styrene-acrylonitrile copolymers, and mixtures of at least two of the polymers mentioned.

22. The multilayer structure as claimed in claim 20, wherein the barrier layer is formed from a precursor selected from the group consisting of silanes, disilanes, tetramethyldisiloxane (TMDSO), hexamethyldisiloxane (HMDSO), tetraethyl orthosilicate (TEOS), hexamethyldisilanes, octamethylcyclotetrasiloxane (D4) and tetramethylcyclotetrasiloxanes, preferably TEOS, HMDSO and D4.

23. The multilayer structure as claimed in claim 20, wherein the barrier layer has a thickness of from 0.5 μm to 2 μm.

24. The multilayer structure as claimed in claim 20, wherein the UV light-absorbing layer is formed from diethylzinc as precursor.

25. The multilayer structure as claimed in claim 24, wherein the UV light-absorbing layer has a thickness of ≧100 nm.

26. The multilayer structure as claimed in claim 24, wherein the UV light-absorbing layer has an optical density at 340 nm of >2.

27. The multilayer structure as claimed in claim 20, wherein the covering layer is formed from a precursor selected from the group consisting of silanes, disilanes, tetramethyldisiloxane (TMDSO), hexamethyldisiloxane (HMDSO), tetraethyl orthosilicate (TEOS), hexamethyldisilanes, octamethylcyclotetrasiloxane (D4) and tetramethylcyclotetrasiloxanes.

28. The multilayer structure as claimed in claim 27, wherein the oxygen and carbon contents of the covering layer have a continuous gradient.

29. The multilayer structure as claimed in claim 27, wherein the covering layer has a thickness of >1 μm.

30. A process for producing a multilayer structure as claimed in claim 20, wherein at least one layer selected from among the barrier layer, UV light-absorbing layer and covering layer is deposited by means of plasma-enhanced chemical or physical vapor deposition.

31. The process for producing a multilayer structure as claimed in claim 30, wherein the Duo-Plasmaline is utilized as plasma source for the deposition.

32. The process for producing a multilayer structure as claimed in claim 31, wherein the frequency of the plasma source is 13.56 MHz, 27.12 MHz, 915.0 MHz, 2.45 GHz or 5.8 GHz.

33. The process for producing a multilayer structure as claimed in claim 31, wherein the ratio of pump power in m³/h to the volume of the vacuum chamber in m³ is greater than 10 000 l/h.

34. The process for producing a multilayer structure as claimed in claim 31, wherein the pressure in the vacuum chamber at maximum pump power and at maximum gas flows of precursors, carrier gases and reactive gases in the absence of the plasma required for deposition is less than 1.5 mbar.

35. A multilayer structure produced by a process as claimed in claim 30.

36. A method comprising utilizing the multilayer structure as claimed in claim 20 for glazing or screens in traffic means, in building and construction, for components in the E&E and IT sector, films or plates.

37. A shaped part containing the multilayer structure as claimed in claim 20.

38. An article comprising the multilayer structure as claimed in claim 20 wherein the article is a glazing component, screen in traffic means, a component for use in the E&E or IT sector, a film or plate.
